(19) United States
(12) Patent Application Publication
(10) Pub. No.: US 2008/0197371 A1
(43) Pub. Date: Aug. 21, 2008

(54) Electro-Optical Element with Controlled, in Particular Uniform Functionality Distribution

(75) Inventor: Clemens Ottermann, Holmdel, NJ (US)

Correspondence Address: DeMont & Breyer, LLC, 100 Commons Way, Ste. 250, Holmdel, NJ, 07733, US

(73) Assignee: SCHOTT AG, Mainz (DE)

(21) Appl. No.: 11/813,635

(22) PCT Filed: Jan. 20, 2006
(86) PCT No.: PCT/EP2006/000502

§ 371 Date: Apr. 2, 2008

(30) Foreign Application Priority Data
Jan. 20, 2005 (DE) 10 2005 002 836.5
Jan. 20, 2005 (DE) 20 2005 000 979.2

(51) Int. Cl. H01L 33/00; H01L 31/00; H01L 21/00

(52) U.S. Cl. 257/98; 438/29; 438/69; 257/432; 257/E21.001; 257/E31.001; 257/E33.001

(57) ABSTRACT

For the economical and straightforward production of a flat electro-optical element which has a functional surface with a defined, in particular homogeneous functionality distribution, the invention provides a method comprising the provision of a substrate, the application of a first electrode layer, the application of at least one functional layer, the application of a second electrode layer, and the application of at least one resistance matching layer which has an electrical resistance perpendicularly to the layer plane that varies in at least one horizontal direction along the layer plane.

The invention furthermore provides a method for producing a coated substrate for producing an electro-optical element.

The invention furthermore comprises a correspondingly produced electro-optical element, a coated substrate, as well as the use of a coated substrate for producing an electro-optical element and the use of an electro-optical element.

The invention relates in general to electro-optical elements which are flat or flat at least in subregions, and in particular to flat electro-optical elements having a specific functionality distribution, in particular a functionality distribution which is regular over the functional surface, as well as to a substrate and to a method for their production.

Electro-optical elements can be used in a wide variety of ways, for example as photovoltaic elements, for electrochromic elements, liquid crystal elements or optoelectronic sensors. Another particularly beneficial field of use involves organic electro-optical elements, in particular organic light-emitting diodes.

The electrochromic effect is due to the fact that, when the electrical charge inside a functional layer composite is displaced by applying a suitable voltage, the optical properties of the composite, for example the transmissivity, change. This effect is employed for example for electrically dimmable rearview mirrors in the automotive industry or for large-surface display panels. Switchable glazing based on electrochromic layers is also being used increasingly in buildings in order to control the insolation, instead of slatted blinds, roller blinds or awnings.

Photovoltaic elements typically use suitably doped semiconductors, in order to convert the light incident on a surface into electricity. These elements have found wide use as solar cells.

For sensor technology, various electro-optical effects can be used. A layer system which voltage-dependently emits light that is registered by an array of photodiodes lying underneath, for example, may be used for fingerprint recognition. Also widespread are CMOS or CCD sensors based on photovoltaic reactions, such as are used for example in digital cameras.

One particularly beneficial field of use is that of organic electro-optical elements. Organic electro-optical elements, in particular organic light-emitting diodes (OLEDs), generally consist of two electrode layers with organic layers arranged in between, which contain at least one organic electroluminescent luminophore. The layers are applied onto a support material (substrate), which is typically transparent. Glass substrates are preferably used for this purpose. So that light can be emitted from the component on the substrate side, the electrode facing the substrate, typically the anode, must likewise be rendered transparent. Semiconductor layers with a high conductivity, for example transparent conductive oxides (TCO), in particular ITO (indium tin oxide), are generally used as materials. OLEDs are current-driven components, i.e. during operation a defined current flows through the electrode layers, where it leads to lateral potential differences due to the finite ohmic impedance of the electrode layers. The transverse current between the electrode layers, which flows through the organic luminescent layers, leads to the generation of light which is proportional to the current density. Local differences in the current density therefore lead to locally differing light emission.

For lighting or illumination elements, flat large-surface light sources with a uniform or specific luminance distribution are required. Typically, these components can only be contacted in the edge zone. The conductivity of the materials best known at present for forming transparent electrode layers, however, is not sufficient to be able to consider the electrode layers as equipotential surfaces for the component design. The significant local resistance of the electrode causes voltage drops in the electrode layers, which lead to differing voltage differences between the electrode layers. Differing local current densities are therefore set up transversely to the luminescent layers, which cannot be controlled externally and lead to locally differing luminances. The larger the luminescent surfaces are, the greater the undesired inhomogeneities of the luminance distribution become.

Electrodes with minimal surface resistances would therefore be desirable, which could be regarded as equipotential layers in comparison with the resistances of the organic layers. This would lead to an OLED component which, with a uniform configuration of the functional layers, would emit light uniformly. Furthermore, the ohmic losses of the current flow in the electrodes would be correspondingly small. This is substantially achieved for the cathode, which is typically configured as a metal layer. The transparent layer, however, deviates significantly from the ideal state.

Accordingly, attempts have been made to reduce the surface resistances of the electrode layers by a greater thickness of the layers. Typically, when used as the anode in OLEDs, ITO layers have layer thicknesses of about 100 nm and surface resistances of 10-20 ohms. Increasing the layer thickness generally leads to an increase of the absorption losses in the transparent electrode layer and therefore to a reduction of the emitted light. In the case of the thicker ITO layers, furthermore, interference structures may be created which likewise can lead to intensity reductions or local inhomogeneities due to variations in the interference effect. The deposition of thicker layers also lengthens the process times and therefore increases the component production costs.

Attempts have also been undertaken to increase the conductivity of the transparent electrode layer in other ways. A sufficient increase of the conductivity, however, always leads to a significant increase of the absorption losses in the transparent electrode layer and therefore to a considerable reduction of the emitted light. This entails an unacceptable efficiency of the component, or an unacceptable power consumption in order to achieve a desired luminance.

It is known from WO 00/17911 A1 to reduce the surface resistance of the electrodes by conductive transparent additional layers. Such additional layers, however, increase the production complexity and therefore the costs. Another disadvantage is that this measure is suitable only for improving the uniformity of the luminance distribution of a specific component. As soon as the luminescent surface is enlarged or the luminance overall is increased, sizeable inhomogeneities are again created owing to the voltage drops then resulting in the electrodes. The additional layers per se must furthermore exhibit no substantial absorption in the visible spectrum.

It is known from EP 969517 A1 to reduce the electrode resistance of the electrodes by additional coating with a narrow-meshed metal grid. A disadvantage with this approach is firstly again the significantly increased production complexity due to the additional coating, and therefore increased costs for the OLED component. Furthermore, other processes in the OLED component production may be significantly compromized by the metal grid. For example, shadows may be cast during PVD operations or strips or furrows may be formed during operations of coating from the liquid phase, for example by means of spin coating or dip coating. The risk of short circuits between the electrodes and therefore total destruction of the components may also be increased. The grid structure furthermore forms dark regions on the luminescent surface of the component, since no light can be emitted directly below the grid structure.

In order to improve the homogeneity of the luminance distribution, EP 997058 A1 proposes to combine a transparent electrode and a metal electrode whose surface resistance ratio is about 1. Since the surface resistance of the transparent electrode can be reduced only with a simultaneously increased light loss, the surface resistance ratio is achieved by increasing the surface resistance of the metal electrode. This, however, leads to a significant increase of the internal line resistance of the component and of the ohmic losses resulting from this by about a factor of 2. The required operating voltage is also increased. Moreover, equalizing the surface resistances has a mitigating effect on the luminance inhomogeneity only in very special contacting configurations, while with symmetrical interconnection of the component the resistance ratio has no effect at all. Furthermore, the inhomogeneities cannot be fully eliminated by matched anode and cathode resistances according to EP 997058 A1; in contrast, they are even more pronounced in the case of extended components.

A more homogeneous luminance distribution can also be achieved by subdividing the luminescent surface of the component into separate small luminescent regions. An OLED constructed according to this principle is known, for example, from U.S. Pat. No. 6,515,417 B1. This solution, however, increases very significantly the production complexity and therefore the costs for the OLED component.

It is therefore an object of the invention to present a way of providing an economically and simply producible, improved electro-optical element which has a functional surface with a defined, in particular homogeneous functionality distribution.

This object is directly achieved in a highly surprisingly simple way by a method for producing an electro-optical element as claimed in claim 1, a method for producing a substrate as claimed in claim 64, an electro-optical component as claimed in claim 32, and a coated substrate as claimed in claim 66. The object is furthermore achieved by a use as claimed in claims 69 and 70. Advantageous refinements are the subject matter of the respective dependent claims.

Accordingly, the method according to the invention for producing an electro-optical component comprises the provision of a substrate, the application of a first electrode layer, the application of at least one functional layer, the application of a second electrode layer, and the application of at least one resistance matching layer, which has an electrical resistance perpendicularly to the layer plane that varies in at least one horizontal direction along the layer plane.

The method is particularly advantageously adapted to the production of an organic electro-optical element, in particular an organic light-emitting diode. To this end, the application of the functional layer comprises the application of at least one layer which comprises an organic electro-optical material.

The method may also be adapted to the production of an electrochromic element, for example an electrochromic window element or an electrochromic mirror, in which case the application of the functional layer comprises the application of at least one electrochromic layer. Suitable materials for the electrochromic layer are for example WOₓ, NiOₓ, VOₓ or NbOₓ.

The method may furthermore provide the application of a photovoltaic layer. The functional layer preferably furthermore comprises at least one doped semiconductor layer, in particular a double layer system having a p-doped semiconductor layer and an n-doped semiconductor layer. Such function layers may be used for producing various electro-optical elements, for example a photovoltaic elements or optoelectronic sensors.

By inserting an additional, locally varying resistance matching layer, for example with a locally varying layer thickness or conductivity, functionality profiles specified in wide ranges can readily be achieved, in particular uniform functionality distributions. To this end, the resistance matching layer may in principle be arranged at any position inside the respective layer stack.

In particular, the resistances of the layers of an organic electro-optical element transversely to the layer (typical length dimensioned 0.1 μm) are typically much less than the resistances along the layer (typical length dimensioned 100 μm), so that current transport primarily takes place only transversely to the layer.

The method expediently comprises the application of contact surfaces on the first and second electrode layers, preferably in the edge regions of the layers, in order to apply or tap an electrical voltage between the first and second electrode layers. The contact surfaces are preferably arranged in the edge regions of the electrode layers, for example in order to permit light entry or light exit through transparent electrode layers.

According to the method, a functionality distribution and an operating voltage of the electro-optical element are advantageously specified, and the at least one resistance matching layer is applied so that the electro-optical element essentially has the specified functionality distribution when the specified operating voltage is applied between the first and second electrode layers. During operation, the operating voltage may deviate from the specified value by about ±10%, without this essentially compromising the specified functionality distribution.

According to the method, the at least one resistance matching layer is particularly advantageously applied so that the light exit or light entry surfaces of the electro-optical element have an essentially uniform functionality distribution when a voltage is applied between the first and second electrode layers. The term uniform functionality distribution is intended to mean a functionality distribution which is essentially constant over the functional surface, typically the light exit or light entry surface. For example, the functionality distribution may advantageously be a luminance distribution of a light-emitting element, the distribution of the transmissivity of an electrochromic element or the photosensitivity distribution.

The resistance profile of the resistance matching layer in order to achieve a specific, in particular uniform functionality distribution depends on the geometry of the electro-optical component, the type of contacting of the electrode layers and possibly the operating parameters of the electro-optical component.

For simple geometries of the electro-optical component, for example rectangular or oval geometries in which contacting is provided in particular along opposite edges, the resistance profile of the resistance matching layer may be provided with the aid of simple mathematical relations.

According to the method, therefore, the resistance matching layer may advantageously be applied so that the resistance perpendicularly to the layer plane is minimal at least at one point of the layer plane, and essentially increases in at least one horizontal direction along the layer from the at least one point.

The resistance of the resistance matching layer perpendicularly to the layer plane particularly advantageously increases from the at least one point with minimal resistance toward the edge of the layer essentially quadratically with the distance.

According to the method, for electrode layers with uniform surface resistances over the luminescent surface and particular, in particular symmetrical geometries, the resistance matching layer is advantageously applied so that the resistance of the resistance matching layer perpendicularly to the layer plane has a profile in at least one horizontal direction along the layer plane which is essentially proportional to

$$\frac{m \cdot A + ( 2 - m ) \cdot K}{2} \cdot {r}^{n} ,$$

with
A: uniform surface resistance of the electrode layer provided as the anode,
K: uniform surface resistance of the electrode layer provided as the cathode,
r: distance along the layer plane to a salient point or a salient curve in the layer plane, the resistance of the resistance matching layer perpendicularly to the layer plane being minimal at the salient point or along the salient point,
n: exponent with n>0, in particular with n=2,
m: relative weighting of the electrode resistances, in particular with m=1.

The resistance matching layer may additionally have a constant resistance component over the layer, so that the resistance of the resistance matching layer perpendicularly to the layer plane has a profile in at least one horizontal direction along the layer plane which is essentially described by the equation

$$R ( r ) = {C}_{1} \cdot \frac{m \cdot A + ( 2 - m ) \cdot K}{2} \cdot {r}^{n} + {C}_{2} , \qquad ( 1 )$$

with
R: local electrical resistance of the resistance matching layer perpendicularly to the layer plane,
C₁, C₂: constants independent of the distance r, and with A, K, r, n and m as above.

If the electrodes have known symmetrical inhomogeneities, for example deposition-induced variations of the metal cathode, then these may likewise be reduced or even substantially compensated for by suitable selection of the embodiment of the resistance matching layer.

For arbitrary, unsymmetrical shapes and sizes or symmetry-perturbing contacting, for example point contacts on rectangular functional surfaces, simple analytical expressions cannot generally be provided for the resistance profile of the resistance matching layer. In these cases the resistance profile may be determined by means of numerical methods, or by means of simulations. To this end, for example, the “finite element” method or the inversion of field equation systems may be used.

The application of the at least one resistance matching layer advantageously comprises the application of a fluid coating material, for example by means of a spin coating or dip coating.

Configurations of the invention which permit deliberate local variation of the resistance matching layer in a simple and economical way are particularly advantageous. Printing techniques are suitable in particular for achieving layer thickness variations, for instance flexographic printing, screen printing or electrophotographic printing methods. Inkjet methods or other spraying methods are also particularly suitable.

Accordingly, in order to apply a fluid coating material, the method advantageously comprises printing by means of a computer-controlled printing head, in particular by means of an inkjet printing head, printing by screen printing, printing by flexographic printing or gravure printing, or spraying through a mask.

Besides said printing techniques, all known deposition methods may also be used in principle for applying the resistance matching layer.

Accordingly, the method advantageously comprises the deposition of a layer by physical vapor deposition, in particular by evaporation or sputtering, or by chemical vapor deposition, in particular plasma-induced chemical vapor deposition. Various methods may also be combined in order to apply the impedance matching layer.

There are various possibilities for varying the resistance of the resistance matching layer. Accordingly, the application of the at least one resistance matching layer advantageously comprises the application of layer regions with differing layer thickness and/or differing layer composition and/or differing layer morphology.

The simplest and most readily controllable type of resistance variation is to vary the layer thickness, since the local transverse resistance is directly proportional to the local layer thickness, based on a resistivity of the layer which is homogeneous everywhere and independent of the layer thickness. Said coating methods such as printing techniques or spraying techniques are particularly suitable for this, since these methods make it possible to vary the layer thickness in a straightforward way.

The layer thickness variation may lead to an additional optical effect, for example absorption or interference effects. This effect may likewise lead to variations in the functionality distribution, particularly in the luminance distribution.

This effect offers another possibility for modulating the functionality distribution of the electro-optical component. The resistance profile of the resistance matching layer, in order to achieve a specific functionality distribution by utilizing this effect, may be determined by means of coupled electro-optical simulations taking into account microscopic material properties, transport, recombination and light generation processes.

Particular resistance profiles may also be adjusted by suitable laterally differing dopings of the conductive resistance matching layer, with substances that affect the conductivity. These substances may be added during the deposition of the resistance matching layer, or may subsequently be introduced into the layer via diffusion processes. The latter may be achieved by thermal transfer, local activation, for example via temperature, light or mechanical energy input, printing or the like. The layer thickness may advantageously be kept substantially constant here, so that detrimental local interference effects can be greatly suppressed. In order to ensure long-term stability of the component, according to the method, the diffusion processes do not continue in the finished component.

A variation of the resistance can also be achieved by varying the morphology of the resistance matching layer, particularly in the case of polymer layers, since the morphology has an effect on the local resistivity and therefore the local transverse resistance. Lattice modifications may be adjusted via thermal input profiles when baking, via local activation for example by temperature, light, mechanical energy input or chemical activators, or via particular material compositions.

Of course, the described methods for varying the resistance of the resistance matching layer may also be combined with one another.

For light output and/or light input, the application of the first and/or second electrode layer advantageously comprises the application of an at least partially transparent electrically conductive layer, which comprises in particular ITO (indium tin oxide). Owing to the high material costs of ITO, the first or second electrode layer is advantageously applied as a metal layer at least on the side of the electro-optical element on which no light output and/or light input is required.

Furthermore, the first and second electrode layers of the electro-optical element advantageously have different work functions.

The resistance matching layer is also advantageously applied so that the work function potentials are adapted to the electrical requirements of the function a layer, i.e. to that of the electroluminescent layer stack in the case of an organic electro-optical element.

Depending on the position of the resistance matching layer in the layer sequence of the electro-optical component, there may be different requirements for the transparency of the resistance matching layer.

Furthermore, the materials and production methods of the resistance matching layer are advantageously compatible with the requirements of the electro-optical element, for example in respect of temperature restrictions or solvent resistance, and do not compromise the electroluminescent properties of the component.

In principle, all conductive layer materials which fulfill these constraints are suitable. Examples of suitable inorganic materials comprise ITO (indium tin oxide), SnOₓ, InOₓ, ZnOₓ, TiOₓ, a:C—H as well as doped Si. Suitable organic materials, in particular for organic electro-optical elements, are for example PEDOT (poly(3,4-ethylenedioxythiophene)), PEDOT/PSS (PSS: poly(styrene sulfonic acid)), PANI (polyaniline), anthracene, Alq₃ (tris(8-oxyquinoline)aluminum)), TDP (triphenylenediamine), CuPc (copper phthalocyanine), NPD (N,N′-bis(1-naphthyl)-N,N′-diphenylbenzidine), as well as all materials mentioned as alternatives to PEDOT in the literature.

In the case of organic electro-optical elements, the resistance matching layer is particularly advantageously applied as a hole transport layer, in particular as a PEDOT or PANI layer, since such a layer is typically already a part of a polymer OLED for example, and the correction function to be achieved by the resistance matching layer can therefore be generated particularly simply and economically together with the hole transport functionality in one working step.

The method may furthermore advantageously comprise the application of one or more functional layers, for example hole injection layers, electron blocker layers, hole blocker layers, electron transport layers, hole transport layers and/or electron injection layers. The method may furthermore also comprise the application of at least one ion transport layer and/or ion storage layer.

The method particularly advantageously comprises the application of a light absorption layer, in particular a color-neutral light absorption layer, having light absorption properties varying along the layer plane.

The application of the light absorption layer particularly preferably comprises the application of a photosensitive layer, exposure of the photosensitive layer and development of the photosensitive layer.

Modulation techniques, for example maskings of uniform luminescent layers in order to represent symbols or text or colorations may be used in order to adjust intended functionality distributions, in particular luminance distributions. To this end, the light-absorbing layers may be applied directly onto the component.

Self-controlling optimization of the light profile of light-emitting components individually for each individual component, in order to compensate for statistically distributed local differences, is particularly advantageous.

Self-controlling optimization of the light profile may, be achieved, by first applying a photosensitive layer, for example a photo emulsion, exposing it by appropriately switching the light-emitting electro-optical component on, developing it and thereby adapting it is optimally to each individual component at its local defects, such as coating defects or short circuits. This is followed by fixing the photosensitive layer and expediently applying a protective coating, for example with a lacquer.

Accordingly, the method particularly advantageously comprises exposure of the photosensitive layer by switching the electro-optical element on for a specific period of time, it being switched on by applying a specific voltage between the first and second electrode layers.

Another variant for optimization of the light profile is actively controlled individual coating. To this end, the luminance distribution of the exit luminescent surface of the electro-optical component is recorded by means of a suitable detector system, for example by means of a camera system with image processing, and stored. From the recorded luminance distribution, an absorption density distribution for optimal local correction of the brightness profile is calculated. According to the calculated absorption density distribution, a locally varying absorptive layer is applied onto the light exit surface, for example by means of a spraying or printing process, for example inkjet printing or electrophotographic printing. This is in turn followed by fixing and expediently applying a protective coating. Various organic and inorganic materials may be used for the absorptive layer, for example thermosets, thermoplastics, sol-gel solutions or inks.

Yet another variant consists in actively controlled individual masking, in which a separate mask is produced on a glass or polymer substrate and fixed on the front side of the component.

Other variants of the method for generating the absorption profile comprise, for example, actively controlled individual coating in which the raw luminance is recorded, the correction is calculated and a photoemulsion is exposed for example by means of a guided light beam, as well as the actively controlled individual fixing of absorptive materials in which the raw luminance is recorded, the correction is calculated, and a coating on the component surface is exposed for fixing and forming the absorptive coating.

Another variant comprises the application of a self-regulating phototropic coating.

All described methods for the application of a light absorption layer have the advantage that each individual component can be optimized in respect of the specified luminance distribution.

As an alternative, the absorptive correction layer may also be integrated into the component. Depending on the position in the layer sequence, however, the layer must than additionally have conductivity and be adapted interference-optically or in light reflection profile. Here again, individual adjustment of the local absorption profile is possible by applying a phototropic coating or by adjusting the absorption via external energy input, for example by means of a laser.

Depending on the purpose of the component to be produced, the method may furthermore advantageously comprise the step of applying an at least partially reflective layer or an at least partially reflective layer system, and/or the step of applying an at least partially antireflective layer or an at least partially antireflective layer system.

The invention furthermore relates to an electro-optical element, which can be produced by the method described above.

An electro-optical element according to the invention accordingly comprises a substrate, a first electrode layer, at least one functional layer, a second electrode layer and at least one resistance matching layer, which has an electrical resistance perpendicularly to the layer plane that varies in at least one horizontal direction along the layer plane.

An electro-optical element according to the invention may also be composed of a plurality or multiplicity of separate flat sub-elements, which are for example arranged on a common substrate.

The element is preferably designed as an organic electro-optical element, in particular as an organic light-emitting diode, in which case the functional layer comprises at least one organic electro-optical material.

Another advantageous embodiment of an element according to the invention is an electrochromic element, in which the at least one functional layer comprises at least one electrochromic layer. The electrochromic layer preferably comprises WOₓ, although other materials known to the person skilled in the art also lie within the scope of the invention, for example NiOₓ, VOₓ or NbOₓ.

The functional layer may furthermore preferably comprise a photovoltaic layer. For many purposes, a functional layer which comprises at least one doped semiconductor layer, in particular a double layer system having a p-doped semiconductor layer and an n-doped semiconductor layer, is also advantageous.

Typically, the electrode layer acting as an anode is arranged on the substrate and the electrode layer acting as a cathode is arranged on the layer system lying in between. Of course an inverted system, in which the cathode is supplied on the substrate and the anode is applied on the layer system lying in between, nevertheless also lies within the scope of the invention.

The first and/or second electrode layer of an element according to the invention advantageously has a contact surface in the edge regions in order to apply and/or tap an electrical voltage. When a voltage which corresponds to a specified operating voltage within a tolerance of ±10% is applied between the first and second electrode layers, the light exit and/or light entry surfaces of the element advantageously has essentially a specific functionality distribution, the functionality distribution particularly advantageously corresponding to a uniform distribution over the light exit and/or light entry surface.

The resistance of the resistance matching layer particularly advantageously has a profile as described above for the method. Accordingly, the resistance perpendicularly to the layer plane preferably increases from a point of minimal resistance toward the edge of the layer, in particular quadratically.

The resistance of the resistance matching layer perpendicularly to the layer plane particularly preferably has a profile in at least one horizontal direction along the layer plane which is essentially described by the equation

$$R ( r ) = {C}_{1} \cdot \frac{m \cdot A + ( 2 - m ) \cdot K}{2} \cdot {r}^{n} + {C}_{2}$$

(see above for the quantities used).

The resistance matching layer is advantageously applied by means of one of the following methods:
spin coating,
dip coating,
printing by means of an inkjet printing head,
printing by screen printing, printing by means of flexographic printing or gravure printing,
spraying through a mask,
physical vapor deposition, in particular evaporation or sputtering, or
chemical vapor deposition, in particular plasma-induced chemical vapor deposition.

The resistance matching layer preferably comprises regions with differing layer thickness and/or differing layer composition and/or differing layer morphology.

Examples of suitable materials for the resistance matching layer are those mentioned above in connection with the method.

The electrode layers of an element according to the invention are advantageously designed so that the first and second electrode layers have different work functions. Furthermore, the first and/or second electrode layers are preferably at least partially transparent, and comprise in particular indium tin oxide. Alternatively, the first and/or second electrode layers are advantageously designed as a metal layer. For one-sided light output and/or light input, one of the electrode layers is advantageously designed as a transparent ITO layer and the other as a metal layer.

Advantageously, the element furthermore comprises at least one hole injection layer and/or one electron blocker layer and/or one hole blocker layer and/or one electron transport layer and/or one hole transport layer and/or one electron injection layer and/or one ion transport layer and/or one ion storage layer.

A particularly preferred embodiment of an element according to the invention comprises a light absorption layer, in particular a color-neutral light absorption layer, having light absorption properties varying along the layer plane, which in particular is produced as described above.

The element furthermore advantageously comprises other functional layers, for example antireflection layers.

The shape of the light exit and/or light entry surface of an element according to the invention is particularly advantageously essentially symmetrical, in particular rectangular, round or oval.

For special purposes, for example in the automotive industry, the light exit and/or light entry surface advantageously comprises at least one acutely angled region. This is, for example, the case with a surface in the form of a circle sector.

Particularly in the case of symmetrical shapes, the resistance matching layer has a resistance profile which can then be expressed analytically by Equation 1 given above.

Depending on the purpose, the light exit and/or light entry surface of an element according to the invention may also have free, nonsymmetrical shaping. In these cases, the resistance profile of the resistance matching layer is generally given not by a simple analytical expression, but the result of numerical methods or simulations, for example the “finite element” method or the inversion of field equation systems.

The invention furthermore relates to a method for producing a coated substrate, comprising the steps:
providing a substrate,
applying at least one electrode layer,
applying at least one resistance matching layer, which has an electrical resistance perpendicularly to the layer plane that varies in a horizontal direction along the layer plane, onto the substrate, wherein
   at least one subsurface of the electrode layer is provided as a contact surface and the resistance profile of the resistance matching layer depends on the surface resistance of the electrode layer and on the arrangement of the at least one contact surface.

The application of the at least one electrode layer advantageously comprises the application of an at least partially transparent electrically conductive layer, which comprises in particular indium tin oxide.

Correspondingly, the invention also relates to a coated substrate for producing an electro-optical element, in particular a photovoltaic element, an electrochromic element, or an OLED or PLED, in particular produced by a method as described above, comprising at least one electrode layer and at least one resistance matching layer, which has an electrical resistance perpendicularly to the layer plane that varies in a horizontal direction along the layer plane.

Various materials are suitable as a substrate material of the coated substrate, for example glass, in particular soda-lime glass, glass ceramic and/or plastic, in particular a barrier-coated plastic, and/or combinations thereof.

The electrode layer of the coated substrate is preferably at least partially transparent, and comprises in particular indium tin oxide.

In the described way, a pre-corrected substrate can be provided which may be used in order to achieve uniform functionality distributions, in particular uniform luminance distributions.

The substrate may be supplemented with other functional layers, for example antireflection layers.

The resistance matching layer may be deposited in a separate coating step, or for example integrated into a hole transport layer intended for an organic electro-optical element, which is designed for example as a PEDOT coating. Integration into a PEDOT coating offers the further advantage that the resistance correction layer is adapted very well to the anode in terms of work function.

The resistance matching layer is advantageously designed so that it is not degraded by subsequent cleaning processes. Furthermore, the resistance matching layer is advantageously essentially resistant to solvents of further liquid coatings (for example in the case of polymer OLEDs). The resistance matching layer is furthermore advantageously vacuum-tight and substantially optically inactive in respect of interferences or absorption.

The invention likewise relates to the use of a substrate as described above for producing an electro-optical element, in particular a photovoltaic element, an electrochromic element, or an OLED or PLED, as well as to the use of an electro-optical element as described above
as a lighting means,
as an illumination means,
as a sign panel or luminescent panel,
as a variable sign plate,
as switch or sensor illumination,
as a high- or low-resolution display,
as a digital poster screen or advertising panel,
in lit flooring or light desks,
as a light surface for ambient illumination,
for background illumination of displays,
for special illumination, particularly in microscopy,
for signaling or illumination, particularly in the automotive, aeronautical, nautical or household sector,
as a photovoltaic element,
as an optoelectronic sensor,
as a liquid crystal element,
as an electrochromic window element, or
as an electrochromic mirror.

The invention will be explained in more detail below with the aid of preferred embodiments using the example of an OLED and with reference to the appended drawings. Reference numerals which are the same denote identical or similar parts in the drawings in which, schematically:

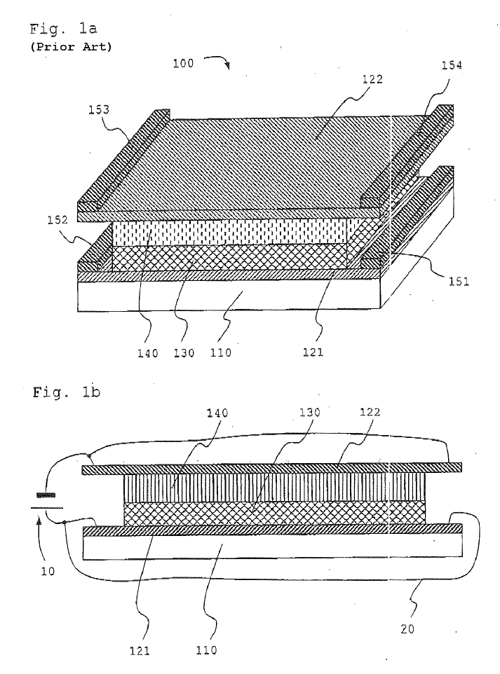

FIG. 1a shows a perspective view of an OLED component according to the prior art,

FIG. 1b shows a cross-sectional view of an OLED component according to the prior art,

FIG. 1c shows the equivalent resistance network of the OLED component in FIGS. 1a and 1b,

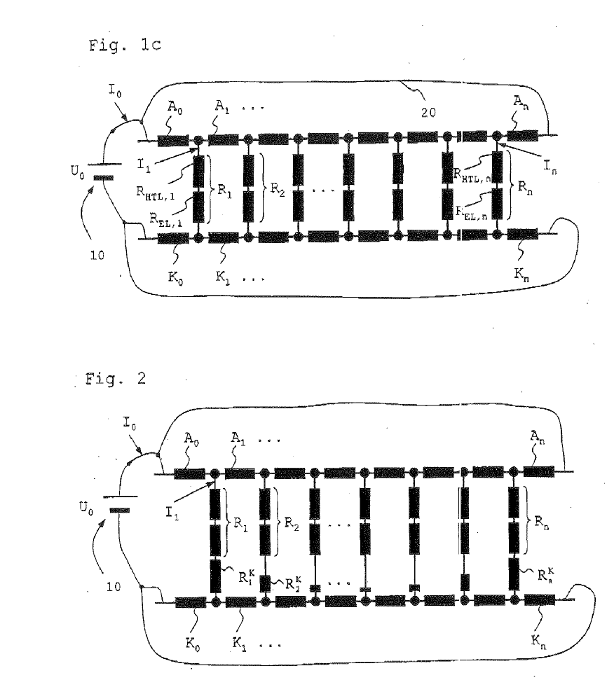

FIG. 2 shows the equivalent resistance network of an OLED component according to the invention,

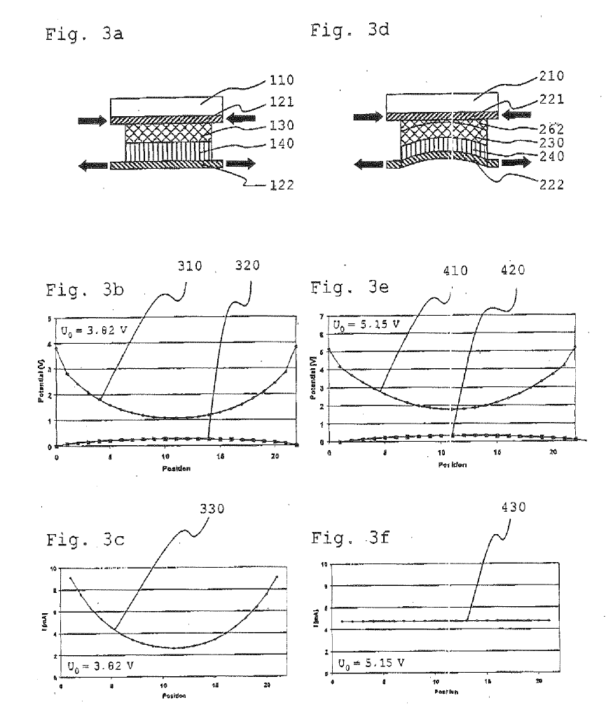

FIGS. 3a-f show a comparison of an OLED component without and with a resistance matching layer in symmetrical contacting,

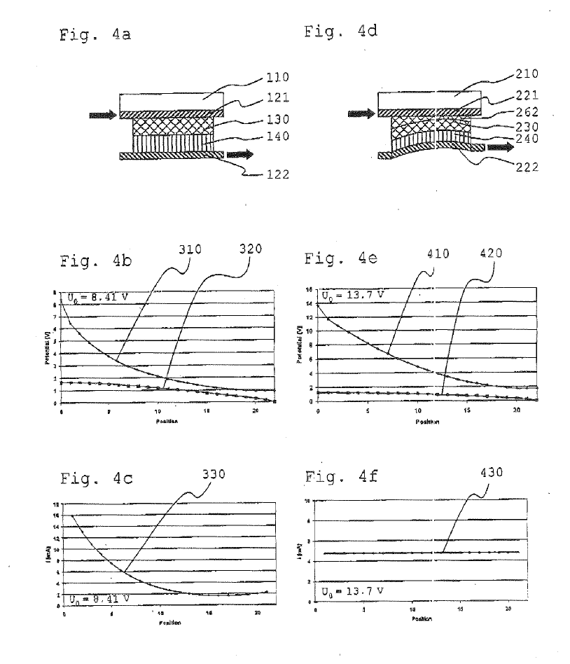

FIGS. 4a-f show a comparison of an OLED component without and with a resistance matching layer in diagonal contacting,

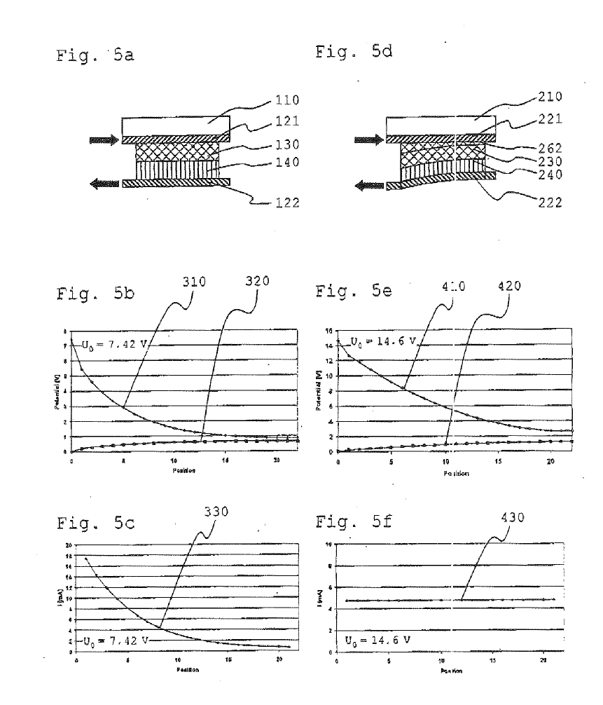

FIGS. 5a-f show a comparison of an OLED component without and with a resistance matching layer in one-sided contacting,

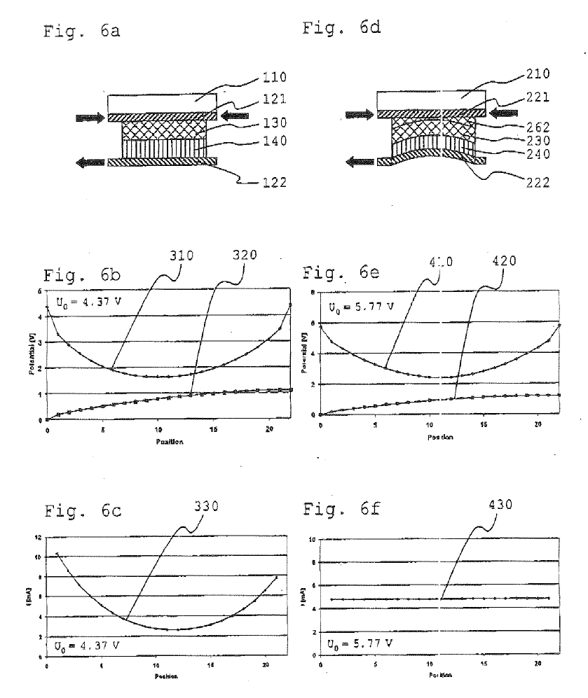

FIGS. 6a-f show a comparison of an OLED component without and with a resistance matching layer in two-sided contacting of the anode and one-sided contacting of the cathode,

FIG. 7a shows potential profiles in an OLED component with a resistance matching layer and symmetrical contacting for various current strengths,

FIG. 7b shows luminances of an OLED component with a resistance matching layer and symmetrical contacting for various current strengths,

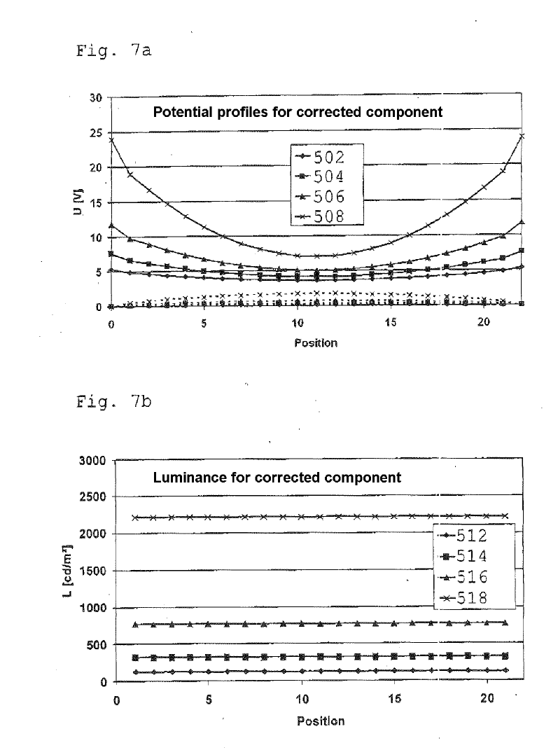

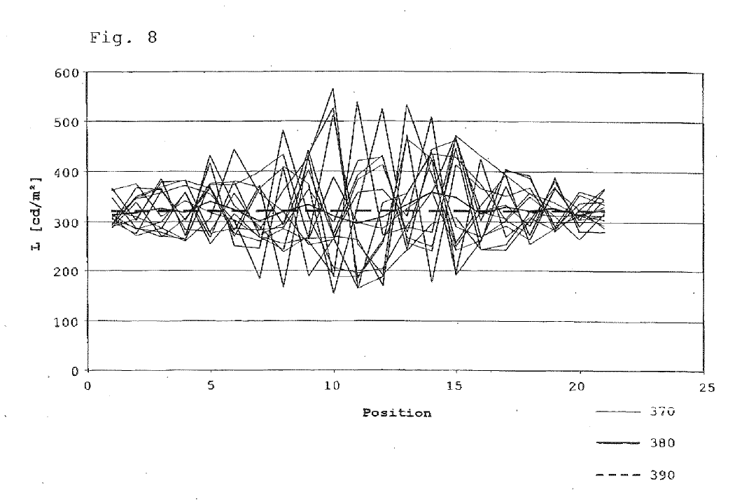

FIG. 8 shows luminance distributions of an OLED component with randomized deviations of the resistance value of the resistance matching layer,

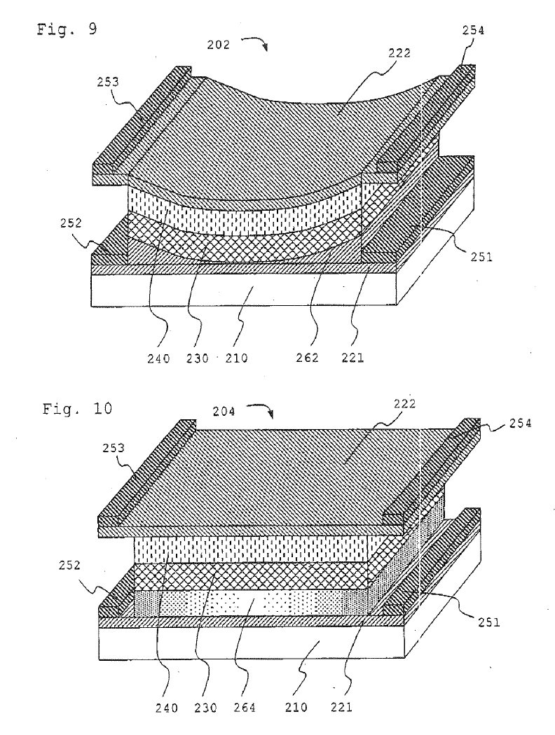

FIG. 9 shows a perspective view of a first rectangular OLED component according to the invention,

FIG. 10 shows a perspective view of a second rectangular OLED component according to the invention,

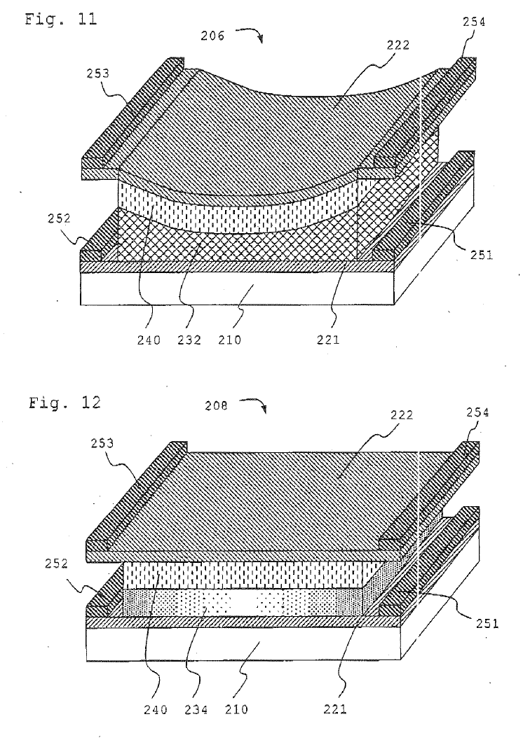

FIG. 11 shows a perspective view of a third rectangular OLED component according to the invention,

FIG. 12 shows a perspective view of a fourth rectangular OLED component according to the invention,

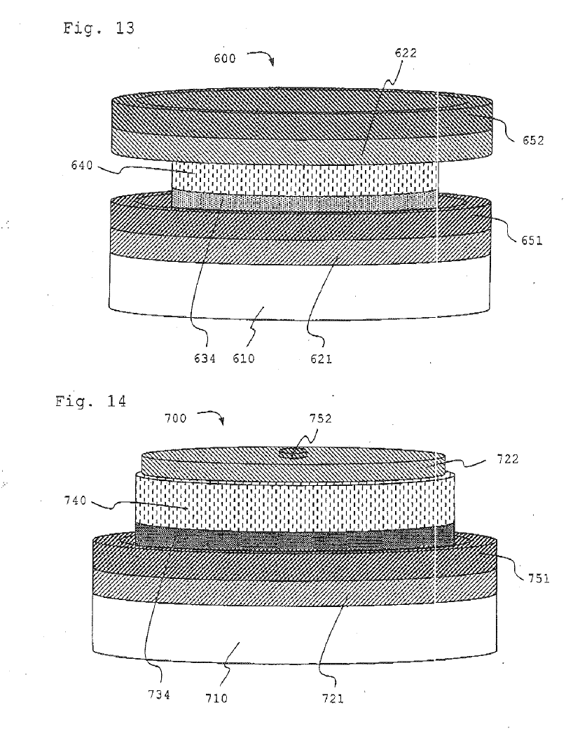

FIG. 13 shows a perspective view of a first round OLED component according to the invention,

FIG. 14 shows a perspective view of a second round OLED component according to the invention,

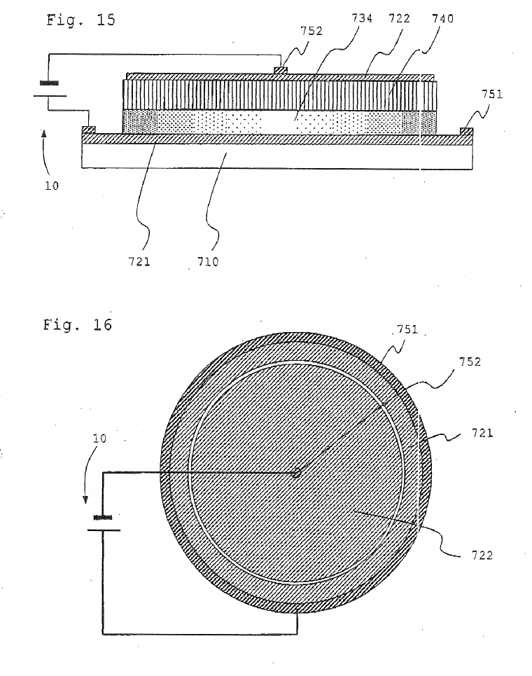

FIG. 15 shows a cross-sectional view of the OLED component in FIG. 14,

FIG. 16 shows a plan view of the OLED component in FIG. 14,

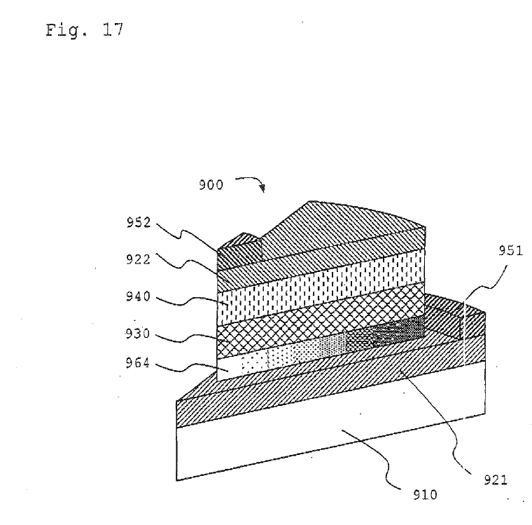

FIG. 17 shows a perspective view of an acutely angled OLED component according to the invention,

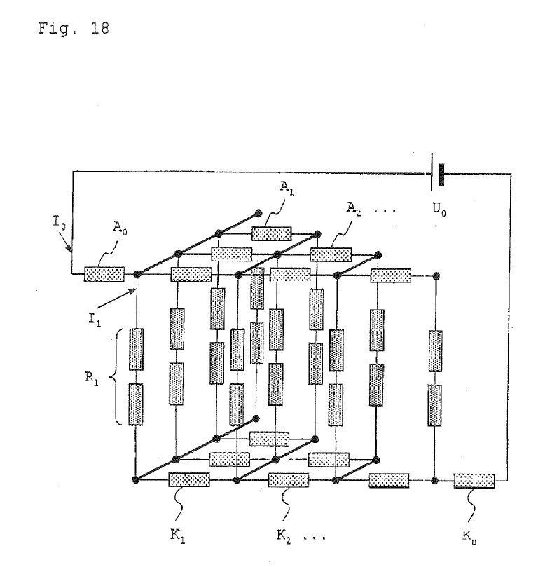

FIG. 18 shows the equivalent resistance network of the OLED component in FIG. 17 without a resistance matching layer,

FIG. 19 shows the equivalent resistance network of the OLED component in FIG. 17 with a resistance matching layer,

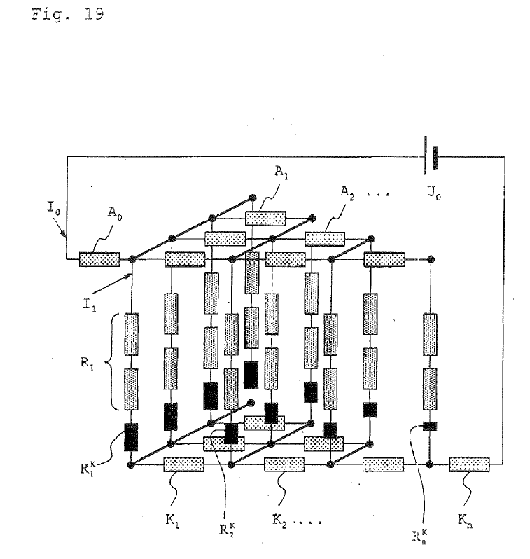

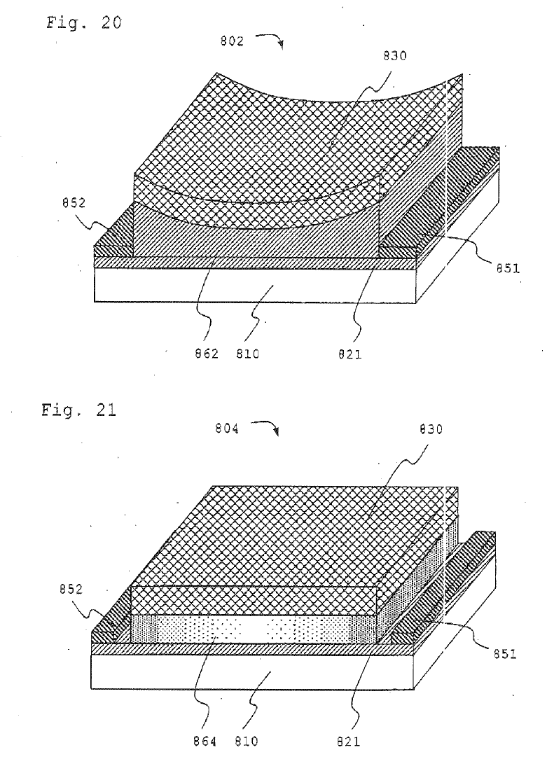

FIG. 20 shows a perspective view of a first substrate according to the invention,

FIG. 21 shows a perspective view of a second substrate according to the invention,

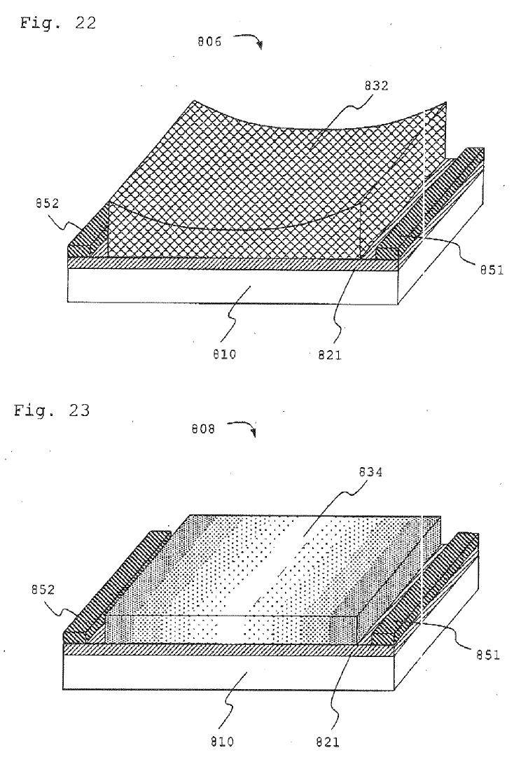

FIG. 22 shows a perspective view of a third substrate according to the invention,

FIG. 23 shows a perspective view of a fourth substrate according to the invention,

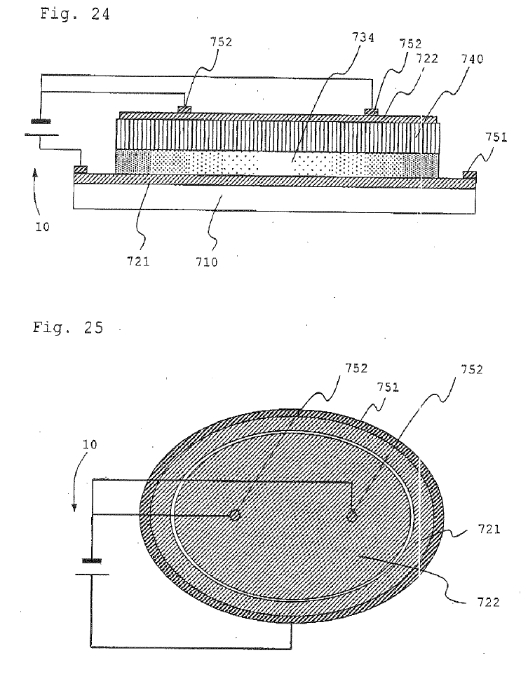

FIG. 24 shows a cross-sectional view of an elliptical OLED component,

FIG. 25 shows a plan view of the OLED component in FIG. 24.

FIGS. 1a and 1b schematically show a rectangular OLED component 100 according to the prior art. FIG. 1 represents a perspective view and FIG. 2 a cross-sectional view through the component 100. The OLED component 100 in this exemplary embodiment is designed as a polymer OLED (PLED) and accordingly comprises 2 organic layers 130 and 140.

On a transparent substrate 110, for example a glass substrate or a correspondingly passivated polymer substrate, a transparent conductive electrode layer 121 is applied as an anode.

This is followed by a compensating layer 130 to compensate for substrate irregularities, which in this exemplary embodiment acts as a hole transport layer (HTL). This is followed by the electroluminescent layer 140 (EL layer) which comprises for example light-emitting polymers (LEP), for example PPV (poly-para-phenylene venylene) or paralene, or shorter-chained organic molecules, for example Alq₃ with corresponding dopants. The polymers are typically deposited from the liquid phase, and the shorter-chained organic molecules from the gas phase by thermal evaporation.

The OLED layer sequence is completed by the cathode layer 122. The exemplary embodiment represented provides symmetrical interconnection. Accordingly, in order to contact the component 100, contact surfaces 151 and 152 are arranged on two opposite sides of the anode layer 121 and contact surfaces 153 and 154 are arranged on two opposite sides of the cathode layer 122. The interconnection with a DC voltage source 10 and corresponding lines 20 is represented in FIG. 1b.

The typically provided encapsulation, for protecting the function layers against destruction by oxygen or water from the environment, is not represented.

FIG. 1c shows an equivalent resistance network of the OLED component represented in FIGS. 1a and 1b. In this idealized network, the resistances inside the organic layers are neglected since, with a length scale in the μm to mm range, these are typically much larger than the surface resistances of the electrode layers or the local resistances transverse to the layers with typical layer thicknesses in the range of 100 nm.

The local transverse resistance through the organic layers is given by the sum of the transverse resistances through the HTL and EL layers, as:

Rᵢ=R_{HTL,i}+R_{EL,i}(Iᵢ) with i=1, . . . , n, (2)

where the resistance value of the EL layer depends on the current strength Iᵢ flowing through. Together with the layer resistances Aᵢ of the anode and Kᵢ of the cathode, the current strengths Iᵢ in the individual branches and the resulting potential differences between the electrodes can be calculated. The layer resistances of the electrode layers can generally be assumed to be constant along the layer plane. The locally emitted luminance is likewise determined by the prevailing current strength. The dependencies of the resistance of the EL layer and of the luminance on the current strength, R_{EL}(Iᵢ) and L_{EL}(Iᵢ), can be directly determined experimentally on laterally small components (pixel devices). Since the individual current strengths Iᵢ per se and therefore R_{EL}(Iᵢ) are unknown, the calculation of the network is carried out iteratively.

The fundamental concept of a particularly advantageous embodiment of the invention is to provide corrections by a resistance matching layer, which preferably allows a constant luminance over the entire luminescent surface of the OLED component.

It is found that the dimensioning of the resistance matching layer in the present approximation depends only on the surface resistances of the two electrode layers. The following parabolic resistance profile applies for the layer in the case of the two-sided symmetrical interconnection represented in FIG. 2

$$\begin{matrix}{R}_{i}^{K} = \frac{A + K}{2} \cdot {( i - \frac{n + 1}{2} )}^{2} , & i = ∈ \{ 1 , … , n \}\end{matrix} \qquad ( 3 )$$

with
A=Aᵢ=const., K=Kᵢ=const., i=ε{1, . . . , n−1} and A₀=Aₙ=2·A, K₀=Kₙ=2·K

FIGS. 3 to 6 represent the electrical current and therefore luminance distributions set up for variously contacted OLED components. For OLED components according to the prior art, inhomogeneities of the luminance are always found. It is clear that with correspondingly extended components and/or large luminances, i.e. large current densities and therefore voltage drops, a uniform luminance distribution cannot be achieved according to the prior art with any interconnection approach.

The interconnection examples and calculated distributions represented in FIGS. 3-6 are respectively based on an equivalent resistance network as represented in FIG. 2 for a corresponding rectangular OLED component with corresponding interconnection. As in FIG. 2, the component is in each case represented with the substrate on top (representation rotated through 180° in comparison with FIGS. 1a and 1b). The interconnection is respectively represented by corresponding arrows in FIGS. 3a, 3d, 4a, 4d, 5a, 5d, 6a and 6d.

For better comparability of the results, the transverse resistances are respectively assumed to be constant and equal. The calculations are furthermore based on a constant cathode resistance K of 1 ohm, a constant anode resistance A of 10 ohms, a constant transverse resistance of 300 ohms, line and contact resistances with A₀=Aₙ=2·A and K₀=Kₙ=2·K, as well as a total current of 100 mA through the component. The operating voltage U₀ respectively required for this total current is respectively specified.

FIG. 3a shows an LED component according to the prior art as represented for example in FIG. 1a, which is interconnected symmetrically on both sides. The light exit direction points upward, and the substrate 110 correspondingly lies on the upper side of the component. The HTL layer 130 and the EL layer 140 are arranged between the transparent anode layer 121 and the cathode layer 122.

FIG. 3b represents the potential profiles 310 and 320 of the anode and cathode layers, respectively. The resulting current density distribution 330 is represented in FIG. 3c.

Conversely, FIG. 3d shows an LED component which is likewise interconnected symmetrically on both sides but, in contrast to the component represented in FIG. 3a, comprises a resistance matching layer 262 in addition to the substrate 210, the electrode layers 221 and 222 as well as the HTL and EL layers 230 and 240.

The resistance matching layer 262 has a laterally varying resistance profile corresponding to Equation (3) above. The corresponding potential profiles 410 and 420 of the anode and cathode layers, respectively, are represented in FIG. 3e. Owing to the resistance matching layer 262 according to the invention, the homogeneous current density distribution 430 represented in the FIG. 3f is obtained. Accordingly, and OLED component corrected in this way has a homogeneous luminance distribution.

The following FIGS. 4a-f, 5a-f and 6a-f differ from FIGS. 3a-f only by a respectively different interconnection of the OLED components.

The correction for diagonal interconnection of an OLED component, as represented in FIGS. 4a-4f, is likewise carried out by means of a parabolic resistance profile of the resistance matching layer corresponding to the equations

$$\begin{matrix}{R}_{i}^{K} = \frac{A + K}{2} \cdot {( i - {i}_{0} )}^{2} , & i = ∈ \{ 1 , … , n \}\end{matrix} \qquad ( 4 )$$

with
A=Aᵢ=const., K=Kᵢ=const., i=ε{1, . . . , n−1} and A₀=Aₙ=2·A, K₀=Kₙ=2·K

The vertex of the parabola, defined by the parameter i₀, is displaced from the middle of the component to the region on the cathode terminal side of the component for the case in which the anode resistance A is greater than the cathode resistance K.

In this case as well, the strength of the corrective resistance profile is determined only by the surface resistances of the anode and cathode, and is independent of the value of the total current or other homogeneous resistive layers, in particular the EL layers. The position of the vertex i₀, however, depends on the ratio of the electrode resistances. Thus, for the case A=K lies in the middle of the component similarly as for the symmetrical interconnection, and for A>>K the component behaves as in the case of one-sided contacting as represented in FIGS. 5a-5f, i.e. the vertex is displaced toward the end side with the cathode contact. For A>K, i₀ lies between these extreme positions. This position is independent of the total current and the behavior of other homogeneously designed EL layers.

In other words, the one-sided interconnection of an OLED component, as represented in FIGS. 5a-5f, corresponds in terms of circuit technology to a half-sided component corresponding to the symmetrical interconnection represented in FIG. 3d, and can therefore be corrected with the same parabolic resistance profile according to Relation (4) if the vertex of the parabola (i) is placed on the end side opposite the contact side.

As revealed by Formula (3), when contacting a symmetrically constructed resistance network on both sides, the vertex lies in the middle of the component i.e.

$${i}_{0} = \frac{n + 1}{2 } ,$$

where n indicates the number of transverse resistances. For the resistance network contacted on one side, the symmetry plane lies slightly outside the last oppositely lying transverse resistance (extra distance Äi=½) since otherwise this resistance would be reflected onto itself and stand only for half the resistance value.

In this case as well, the strength of the corrective resistance profile is determined only by the surface resistances of the anode and cathode, and is independent of the value of the total current or other homogeneous resistive layers, in particular the EL layers. The position of the vertex is independent of the electrode resistances.

In the interconnection represented in FIGS. 6a-6f with two-sided contacting of the anode layer and one-sided contacting of the cathode, the resistance profile of the resistance matching layer follows the basic parabolic profile according to Equation (4) and depends only on the electrode resistances A and K. For A<<K, the resistance profile for this interconnection is the same as that for symmetrical interconnection corresponding to FIGS. 3a-3f, and the vertex i₀ lies in the middle of the component. As the ratio A/K is reduced, the vertex is displaced in the direction of the other side of the component from the cathode contact.

In this case as well, the strength of the corrective resistance profile is determined only by the surface resistances of the anode and cathode, and is independent of the value of the total current or other homogeneous resistive layers, in particular the EL layers.

FIGS. 7a and 7b respectively represent the potential profiles and current distribution as obtained with different total current strengths of between 20 and 500 mA for a symmetrically interconnected OLED component corrected by means of a resistance matching layer. Specifically, FIG. 7a represents the potential profile 502 and FIG. 7b the luminance profile 512 for a current strength of 50 mA, FIG. 7a represents the potential profile 504 and FIG. 7b the luminance profile 514 for a current strength of 100 mA, FIG. 7a represents the potential profile 506 and FIG. 7b the luminance profile 516 for a current strength of 200 mA, FIG. 7a represents the potential profile 508 and FIG. 7b the luminance profile 518 for a current strength of 500 mA.

The calculations based on a constant cathode resistance K of 1 ohm, a constant anode resistance A of 10 ohms, a constant transverse resistance of 300 ohms, line and contact resistances with A₀, K₀, Aₙ and Kₙ which are twice as large as A and K, as well as a total current of 100 mA through the component. The calculations are furthermore based on a real OLED characteristic.

It is found that the profile of the resistance matching layer is independent of the total current strength. Furthermore, any desired other layers may be applied onto the resistance matching layer (PEDOT, EL, etc.). So long as these layers in total have a uniform transverse resistance with the same current dependency, the uniformity of the transverse current remains unchanged. The uniform resistance of the further layers, in conjunction with the uniform current distribution, leads to a potential increase between the two electrode layers which is constant over the surface.

The generation of uniform luminescent surfaces by means of a resistance matching layer is robust in respect of perturbations of the local component properties. “Noises” amounting to ±5% in the corrective resistance values and in the OLED characteristic lead only to a fluctuation of the local brightness around the values of the unperturbed case, but not to any significant systematic deviation from uniformity. The results of corresponding calculations are shown by FIG. 8, in which various luminance profiles 370 are represented for corrective resistance values or OLED characteristics perturbed by ±5%. The respective average values 380 and the statistical average 390 are likewise represented.

For rectangular components, the circuit networks described above comprising discrete resistances can be converted into continuous layer models by replacing the discrete relations for the corrective resistance profiles according to Equation (4) by the following generalization:

$${R}_{corr} ( x ) = {C}_{1} \cdot \frac{m \cdot A + ( 2 - m ) \cdot K}{2} \cdot {( x - {x}_{0} )}^{n} + {C}_{2} , \qquad ( 5 )$$

with
R_{corr}: local electrical resistance of the resistance matching layer perpendicularly to the layer plane,
A: uniform surface resistance of the electrode layer provided as the anode,
K: uniform surface resistance of the electrode layer provided as the cathode,
x₀: position of the vertex of the resistance profile,
x: coordinate along the layer plane between the terminal sides,
C₁, C₂: constants,
n: exponent with n>0, in particular with n=2,
m: relative weighting of the electrode resistances, in particular with m=1.

The constant C₂ describes a constant resistance base contribution, which is for example due to coating technology. For example, the resistance matching layer will generally have a minimal thickness greater than zero at the vertex.

A prerequisite for applicability of the above equation is that the contacting takes place over the entire length of the component sides, or the surface resistance in the contacting region is small compared to the typical resistances of the electrode layer.

Owing to voltage drops in the contacting region, in the absence of countermeasures, perturbations of the luminance uniformity are to be expected with local, for example essentially point-like contacts. This effect, however, may also be corrected by a suitable choice of the embodiment of the resistance matching layer.

FIG. 9 schematically shows a perspective view of a rectangular OLED component 202 according to the invention. In this exemplary embodiment, a first electrode layer 221 provided as an anode, which has contactings 251 and 252 on opposite sides for symmetrical interconnection, is arranged on a substrate 210. The electrode layer 221 is preferably designed as a transparent ITO layer for light output through the substrate. The OLED component in this exemplary embodiment is designed as a PLED, and accordingly comprises a hole transport layer 230 and an electroluminescent layer 240. The resistance matching layer 262 is arranged between the electrode layer 221 and the hole transport layer 230. The OLED layer sequence is completed by the electrode layer 222 provided as a cathode, which has contactings 253 and 254 on opposite sides for symmetrical interconnection. The OLED component represented in FIG. 9 is therefore essentially the same as the component in FIG. 1a, which additionally comprises the resistance matching layer 262.

In the exemplary embodiment represented in FIG. 9, the resistance matching layer 262 is designed so that the electrical resistance is varied by variation of the layer thickness. The resistance profile corresponds to a profile according to Equation (5) above with x being the coordinate on an axis along the layer plane, which connects the contactings 251 and 252 and extends perpendicularly to their principal axes, and with x₀ placed in the middle of the layer. Accordingly, the OLED component 202 has an essentially homogeneous luminance distribution over the entire light exit surface.

Instead of by varying the layer thickness, the variation of the resistance of the resistance matching layer may also be achieved in another way, for example by varying the layer composition and/or the layer morphology. This is done in the embodiment of an OLED component 204 according to the invention as represented in FIG. 10. This embodiment 204 corresponds to the embodiment 202 represented in FIG. 9, the resistance matching layer 264 having the same resistance profile as the layer 262, with the difference that the layer 264 has a layer composition varying along the layer plane with constant layer thickness. The layer composition may, for example, be varied by applying different compositions of layer materials by suitable printing methods, the different compositions having different resistivities.

FIGS. 11 and 12 represent preferred embodiments of OLED components 206 and 208 according to the invention, in which the HTL layer and the resistance matching layer are respectively combined to form a corrected HTL layer 232 or 234. This offers the particular advantage that no additional working step is required for application of the resistance matching layer.

The corrected HTL layer 232 represented in FIG. 11 has a layer thickness varying along the layer plane, a homogeneous luminance distribution of the OLED component being achieved by its profile which in turn corresponds to Equation (5). In the exemplary embodiment represented in FIG. 12, the resistance profile of the corrected HTL layer 234 is provided by varying the layer composition and/or the layer morphology.

Of course, other designs also lie within the scope of the invention besides the rectangular OLED components 202 to 208 represented in FIGS. 9 to 12.

FIG. 13 schematically represents a perspective view of an embodiment of a round OLED component 600 according to the invention. This component 600 comprises a round substrate 610, on which an anode layer 621 is arranged surface-wide. In the edge region of the anode layer 621, an annular contact surface 651 is provided for contacting. Between the anode layer 621 and the cathode layer 622 arranged above, a corrected HTL layer 634 and an electroluminescent layer 640 are arranged. In this exemplary embodiment, the cathode layer 622 has an annular contact surface 652. The corrected HTL layer 634 has a suitable resistance profile along the layer plane, which increases from the middle of the layer toward the edge so that the OLED component 600 has a homogeneous luminance distribution.

The round OLED component 700 represented in FIG. 14 likewise comprises a substrate 710, on which an anode layer 721 with an annular contact surface 751 is arranged. A corrected HTL layer 734 and an EL 740 are arranged on the anode layer. 721. The layer sequence is in turn completed by the cathode layer 722. In contrast to the embodiment 600 represented in FIG. 13, the cathode layer 722 of the component 700 has a contact surface 752 arranged in the middle of the layer. The essentially point-like or small-area contact surface 752 simplifies contacting of the component 700.

FIGS. 15 and 16 schematically show respectively a cross-sectional view and a plan view of the component 700 represented in FIG. 14. Likewise represented in each case is a voltage source 10, to which the OLED component 700 is connected. The resistance profile of the corrected HTL layer 734, produced in this embodiment by varying the layer composition and/or the layer morphology, is indicated by corresponding shading in FIG. 15. The resistance transversely to the layer plane increases essentially linearly in this exemplary embodiment from the middle of the layer toward the edge.

FIG. 17 shows a particularly preferred embodiment of an OLED component 900 according to the invention, which has an acutely angled design. In the component 900, a separate HTL layer 930 and resistance matching layer 964 are provided. Apart from this, the OLED component 900 essentially represents a segment of the round OLED component 700 represented in FIGS. 14 to 16. Accordingly, the OLED component 900 comprises a substrate 910, and anode layer 921 arranged thereon with a contacting surface 951 arranged at the edge, as well as an EL layer 940 arranged above the resistance matching layer 964 and the HTL layer 930. The layer sequence is in turn completed by a cathode layer 922, which in this embodiment has small-area contacting 952.

Similar to the equivalent resistance network represented in FIG. 1c, FIG. 18 shows an equivalent resistance network for the OLED component 900 represented in FIG. 17, but without the resistance matching layer 964.

The local transverse resistance through the organic layers is given by the sum of the transverse resistances through the HTL and EL layers according to Equation (2) above, the resistance value of the EL in turn depending on the current strength Iᵢ flowing through. Together with the layer resistances Aᵢ of the anode layer and Kᵢ of the cathode layer and based on the applied voltage U₀ and the total current I₀, the current strengths Iᵢ in the individual branches and the resulting potential differences between the electrode layers can be calculated iteratively.

The calculations yield a linear or approximately linear decrease of the contact resistances Rᵢ^{K} (i=1, . . . , n) represented in FIG. 19 with increasing i in order to achieve a homogeneous luminance distribution of this component.

Since the resistance profile of the resistance matching layer for a homogeneous luminance distribution of the OLED component is independent of the current strength, as represented for example in FIG. 7b, the invention particularly advantageously provides a pre-corrected substrate which is coated with a resistance matching layer.

Various embodiments of such a substrate according to the invention are represented in FIGS. 20 to 23. The substrates 802, 804, 806 and 808 represented respectively comprise a substrate 810 with an electrode layer 821 applied thereon, which is preferably designed as an ITO layer and has contacting surfaces 851 and 852.

The substrate 802 has a resistance matching layer 862, which varies in layer thickness along the layer plane and is preferably likewise designed as a transparent ITO layer. The resistance matching layer 862 may, as represented in FIG. 20, for example, also be coated with an HTL layer 830 which may preferably be designed as a PEDOT layer.

In the embodiment represented in FIG. 21, the resistance matching layer 864 is designed so that the resistance variation along the layer plane is produced by varying the layer composition and/or the layer morphology and/or the density of the layer with a constant layer thickness. An HTL layer 830 is also provided in this exemplary embodiment.

The resistance matching layer may also advantageously be integrated into the HTL coating, designed for example as a PEDOT layer. Corresponding embodiments of a coated substrate 806 and 808 according to the invention are represented in FIGS. 22 and 23, respectively. The substrate 806 comprises an HTL layer 832 pre-corrected by varying the layer thickness, and the substrate 808 comprises an HTL layer 834 pre-corrected by varying for example the layer morphology.

The resistance matching layer 862 or 864, or the pre-corrected HTL layer 832 or 834, is advantageously designed so that it is not degraded by subsequent cleaning processes and is essentially resistant to solvents of further liquid coatings. The resistance matching layer is furthermore advantageously vacuum-tight and substantially optically inactive in respect of interferences or absorption.

An example of an oval design is represented in FIGS. 24 and 25. The elliptical OLED component, schematically represented as a cross-sectional view and as a plan view in FIGS. 24 and 25, comprises a substrate 710 on which an anode layer 721 is arranged, at the edge of which a contact surface 751 is provided. A corrected HTL layer 734 and an EL layer 740 are arranged on the anode layer 721. The layer sequence is completed by the cathode layer 722. The cathode layer 722 of the component has to contact surfaces 752 respectively arranged at the foci of the ellipse. The essentially point-like or small-area contact surfaces 752 simplify contacting of the component 700.

### LIST OF REFERENCES

10 voltage source
20 terminal line
100 OLED component
110 substrate
121, 122 electrode layer
130 hole transport layer
140 electroluminescent layer
151-154 contactings
202-208 embodiments of an OLED component according to the invention with a rectangular design
210 substrate
221, 222 electrode layer
230 hole transport layer
232, 234 corrected hole transport layer
240 electroluminescent layer
251-254 contactings
262, 264 resistance matching layer
310 potential profile along the anode layer for uncorrected component
320 potential profile along the cathode layer for uncorrected component
330 profile of the current strength transversely to the layer plane as a function of the position along the electrode layers for uncorrected component
370 luminance profiles for correction resistance values or OLED characteristics perturbed by ±5%
380 average value of the perturbed luminance profiles
390 statistical average
410 potential profile along the anode layer for corrected component
420 potential profile along the cathode layer for corrected component
430 profile of the current strength transversely to the layer plane as a function of the position along the electrode layers for corrected component
502 potential profile for corrected component with a current strength of 50 mA
504 potential profile for corrected component with a current strength of 100 mA
506 potential profile for corrected component with a current strength of 200 mA
508 potential profile for corrected component with a current strength of 500 mA
512 luminance profile for corrected component with a current strength of 50 mA
514 luminance profile for corrected component with a current strength of 100 mA
516 luminance profile for corrected component with a current strength of 200 mA
518 luminance profile for corrected component with a current strength of 500 mA
600 OLED component with round design
610 substrate
621, 622 electrode layer
634 corrected hole transport layer
640 electroluminescent layer
651, 652 contactings
700 OLED component with round design
710 substrate
721, 722 electrode layer
734 corrected hole transport layer
740 electroluminescent layer
751, 752 contactings
802-808 embodiments of an OLED component according to the invention with a rectangular design
810 substrate
821 electrode layer
830 hole transport layer
832, 834 corrected hole transport layer
851, 852 contactings
862, 864 resistance matching layer
900 OLED component with acutely angled cross section
910 substrate
921, 922 electrode layer
930 hole transport layer
964 resistance matching layer
940 electroluminescent layer
951, 952 contactings
A₀-Aₙ anode resistances
K₀-Kₙ cathode resistances
R₁-Rₙ local layer resistances
I₁-Iₙ local current strengths
R_{HTL,1}-R_{HTL,n} local resistances of the hole transport layer
R_{EL,1}-R_{EL,n} local resistances of the electroluminescent layer
U₀ voltage applied between anode and cathode
I₀ total current strength through the component
R₁^{K}-Rₙ^{K} local resistances of the resistance matching layer

1. A method for producing an electro-optical element (100, 202-208, 600, 700, 900) comprising the steps
providing a substrate (110, 610, 710, 810),
applying a first electrode layer (121, 221, 721),
applying at least one functional layer
applying a second electrode layer (122, 222, 722), characterized by the step of
applying at least one resistance matching layer (262, 264, 862, 864, 964), which has an electrical resistance perpendicularly to the layer plane that varies in at least one horizontal direction along the layer plane, wherein the resistance matching layer (262, 264, 862, 864, 964) is applied with a resistance profile depending on the geometry of the electro-optical element (100, 202-208, 600, 700, 900) and the type of contacting of the electrode layers in order to achieve a specific functionality distribution of a light exit or light entry surface of the electro-optical element.

2. The method as claimed in claim 1 for producing an organic electro-optical element (100, 202-208, 600, 700, 900), wherein the application of at least one functional layer comprises the application of at least one layer which comprises at least one organic electro-optical material.

3. The method as claimed in claim 1 for producing an electrochromic element, wherein the application of at least one functional layer comprises the application of at least one electrochromic layer.

4. The method as claimed in claim 3, wherein the electrochromic layer comprises WOₓ, NiOₓ, VOₓ and/or NbOₓ.

5. The method as claimed in claim 1, wherein the application of at least one functional layer comprises the application of at least one photovoltaic layer.

6. The method as claimed in claim 1, wherein the at least one functional layer comprises at least one doped semiconductor layer.

7. The method as claimed in claim 1, furthermore comprising the application of contact surfaces in the edge regions of the first (121, 221, 721) and second (122, 222, 722) electrode layers in order to apply or tap an electrical voltage between the first (121, 221, 721) and second (122, 222, 722) electrode layers.

8. The method as claimed in claim 1, characterized by the steps:
specifying a functionality distribution at least of one surface of the electro-optical element, and
specifying a value for an operating voltage of the electro-optical element in order to apply a voltage with the predetermined value of the operating voltage ±10% between the first (121, 221, 721) and second (122, 222, 722) electrode layers during operation of the electro-optical element, wherein the resistance matching layer (262, 264, 862, 864, 964) is applied with a resistance profile depending on the specified value of the operating voltage in order to achieve the specific functionality distribution.

9. The method as claimed in claim 1, wherein the at least one resistance matching layer (262, 264, 862, 864, 964) is applied in order to achieve an essentially uniform functionality distribution.

10. The method as claimed in claim 8, wherein the functionality distribution is a luminance distribution.

11. The method as claimed in claim 1, wherein the resistance of the resistance matching layer (262, 264, 862, 864, 964) perpendicularly to the layer plane is minimal at least at one point of the layer plane, and essentially increases in at least one horizontal direction from the at least one point toward the edge of the layer.

12. The method as claimed in claim 1, wherein the resistance of the resistance matching layer (262, 264, 862, 864, 964) perpendicularly to the layer plane is minimal at least at one point of the layer plane, and increases essentially quadratically with the distance from the at least one point in at least one horizontal direction from the at least one point toward the edge of the layer.

13. The method as claimed in claim 1, wherein the resistance of the resistance matching layer (262, 264, 862, 864, 964) perpendicularly to the layer plane has a profile in at least one horizontal direction along the layer plane which is essentially proportional to
$$\frac{m \cdot A + ( 2 - m ) \cdot K}{2} \cdot {r}^{n} ,$$
with
A: uniform surface resistance of the electrode layer (121, 122, 221, 222, 721, 722) provided as the anode,
K: uniform surface resistance of the electrode layer (121, 122, 221, 222, 721, 722) provided as the cathode,
r: distance along the layer plane to a salient point or a salient curve in the layer plane, the resistance of the resistance matching layer (262, 264, 862, 864, 964) perpendicularly to the layer plane being minimal at the salient point or along the salient point,
n: exponent with n>0,
m: relative weighting of the electrode resistances.

14. The method as claimed in claim 1, wherein the resistance of the resistance matching layer (262, 264, 862, 864, 964) perpendicularly to the layer plane has a profile in at least one horizontal direction along the layer plane which is essentially described by the equation
$$R ( r ) = {C}_{1} \cdot \frac{m \cdot A + ( 2 - m ) \cdot K}{2} \cdot {r}^{n} + {C}_{2} ,$$
with
R: local electrical resistance of the resistance matching layer (262, 264, 862, 864, 964) perpendicularly to the layer plane,
A: uniform surface resistance of the electrode layer (121, 122, 221, 222, 721, 722) provided as the anode,
K: uniform surface resistance of the electrode layer (121, 122, 221, 222, 721, 712) provided as the cathode,
r: distance along the layer plane to a salient point or a salient curve in the layer plane, the resistance of the resistance matching layer (262, 264, 862, 864, 964) perpendicularly to the layer plane being minimal at the salient point or along the salient point,
C₁, C₂: constants independent of the distance r,
n: exponent with n>0,
m: relative weighting of the electrode resistances.

15. The method as claimed in claim 1, wherein the application of the at least one resistance matching layer (262, 264, 862, 864, 964) comprises the application of a fluid coating material.

16. The method as claimed in claim 15, wherein the application of the fluid coating material is carried out by means of spin coating or dip coating.

17. The method as claimed in claim 15, wherein the application of the fluid coating material comprises at least one of the steps
printing by means of a computer-controlled printing head,
printing by flexographic printing or gravure printing,
printing by screen printing or
spraying through a mask.

18. The method as claimed in claim 1, wherein the application of the at least one resistance matching layer (262, 264, 862, 864, 964) comprises the deposition of a layer by physical vapor deposition or by chemical vapor deposition.

19. The method as claimed in claim 1, wherein the application of the at least one resistance matching layer (262, 264, 862, 864, 964) comprises the application of layer regions with differing layer thickness and/or differing layer composition and/or differing layer morphology.

20. The method as claimed in claim 1, wherein the application of the at least one resistance matching layer (262, 264, 862, 864, 964) comprises the application of at least one of the materials ITO, SnOₓ, InOₓ, ZnOₓ, TiOₓ, a:C—H, doped Si, PEDOT, PEDOT/PSS, PANI, anthracene, Alq₃, TDP, CuPu or NPD.

21. The method as claimed in claim 1, wherein the at least one resistance matching layer (262, 264, 862, 864, 964) is applied as a hole transport layer (634, 734).

22. The method as claimed in claim 1, wherein the first (121, 221, 721) and second (122, 222, 722) electrode layers have different work functions.

23. The method as claimed in claim 1, wherein the application of the first (121, 221, 721) and/or second (122, 222, 722) electrode layers comprises the application of at least partially transparent electrically conductive layer.

24. The method as claimed in claim 1, wherein the application of the first (121, 221, 721) and/or second electrode (122, 222, 722) layers comprises the application of a metal layer.

25. The method as claimed in claim 1, characterized by the step of applying at least one hole injection layer and/or electron blocker layer and/or hole blocker layer and/or electron transport layer and/or hole transport layer (130, 230, 634, 734, 830, 930) and/or electron injection layer.

26. The method as claimed in claim 1, characterized by the step of applying at least one ion transport layer and/or one ion storage layer.

27. The method as claimed in claim 1, characterized by the application of a light absorption layer having light absorption properties varying along the layer plane.

28. The method as claimed in claim 27, wherein the application of the light absorption layer comprises the following steps:
applying a photosensitive layer,
exposing the photosensitive layer,
developing the photosensitive layer.

29. The method as claimed in claim 27, wherein the electro-optical element is designed as a light-emitting element and the photosensitive layer is exposed by switching the electro-optical element on for a specific period of time, it being switched on by applying a specific voltage between the first (121, 221, 721) and second (122, 222, 722) electrode layers.

30. The method as claimed in claim 1, characterized by the step of applying an at least partially reflective layer or an at least partially reflective layer system.

31. The method as claimed in claim 1, characterized by the step of applying an at least partially antireflective layer or an at least partially antireflective layer system.

32. An electro-optical element, comprising
a substrate (110, 610, 710, 810),
a first electrode layer (121, 221, 721),
at least one functional layer and
a second electrode layer (122, 222, 722), characterized by
at least one resistance matching layer (262, 264, 862, 864, 964), which has an electrical resistance perpendicularly to the layer plane that varies in at least one horizontal direction along the layer plane, wherein the resistance matching layer (262, 264, 862, 864, 964) has a resistance profile depending on the geometry of the electro-optical element (100, 202-208, 600, 700, 900) and the type of contacting of the electrode layers in order to achieve a specific functionality distribution of a light exit or light entry surface of the electro-optical element.

33. The element as claimed in claim 32, which is designed as an organic electro-optical element (100, 202-208, 600, 700, 900), wherein the functional layer comprises at least one organic electro-optical material.

34. The element as claimed in claim 32, designed as an electrochromic element, wherein the at least one functional layer comprises at least one electrochromic layer.

35. The element as claimed in claim 34, wherein the electrochromic layer comprises WOₓ, NiOₓ, VOₓ and/or NbOₓ.

36. The element as claimed in claim 32, wherein the at least one functional layer comprises at least one photovoltaic layer.

37. The element as claimed in claim 32, wherein the at least one functional layer comprises at least one doped semiconductor layer.

38. The element as claimed in claim 32, wherein the first (121, 221, 721) and/or second (121, 221, 722) electrode layer has a contact surface in the edge regions in order to apply or tap an electrical voltage.

39. The element as claimed in claim 32, wherein the light exit and/or light entry surfaces of the element have a specific functionality distribution when a voltage with the value of a specified operating voltage ±10% is applied between the first (121, 221, 721) and second (121, 221, 722) electrode layers.

40. The element as claimed in claim 32, wherein the light exit and/or light entry surfaces of the element have an essentially uniform functionality distribution.

41. The element as claimed in claim 39, wherein the functionality distribution is a luminance distribution.

42. The element as claimed in claim 32, wherein the resistance of the resistance matching layer (262, 264, 862, 864, 964) perpendicularly to the layer plane is minimal at least at one point of the layer plane, and essentially increases in at least one horizontal direction from the at least one point toward the edge of the layer.

43. The element as claimed in claim 32, wherein the resistance of the resistance matching layer (262, 264, 862, 864, 964) perpendicularly to the layer plane is minimal at least at one point of the layer plane, and increases essentially quadratically with the distance from the at least one point in at least one horizontal direction from the at least one point toward the edge of the layer.

44. The element as claimed in claim 32, wherein the resistance of the resistance matching layer (262, 264, 862, 864, 964) perpendicularly to the layer plane has a profile in at least one horizontal direction along the layer plane which is essentially proportional to
$$\frac{m \cdot A + ( 2 - m ) \cdot K}{2} \cdot {r}^{n} ,$$
with
A: uniform surface resistance of the electrode layer provided as the anode,
K: uniform surface resistance of the electrode layer provided as the cathode,
r: distance along the layer plane to a salient point or a salient curve in the layer plane, the resistance of the resistance matching layer (262, 264, 862, 864, 964) perpendicularly to the layer plane being minimal at the salient point or along the salient point,
n: exponent with n>0,
m: relative weighting of the electrode resistances.

45. The element as claimed in claim 32, wherein the resistance of the resistance matching layer (262, 264, 862, 864, 964) perpendicularly to the layer plane has a profile in at least one horizontal direction along the layer plane which is essentially described by the equation
$$R ( r ) = {C}_{1} \cdot \frac{m \cdot A + ( 2 - m ) \cdot K}{2} \cdot {r}^{n} + {C}_{2} ,$$
with
R: local electrical resistance of the resistance matching layer (262, 264, 862, 864, 964) perpendicularly to the layer plane,
A: uniform surface resistance of the electrode layer provided as the anode,
K: uniform surface resistance of the electrode layer provided as the cathode,
r: distance along the layer plane to a salient point or a salient curve in the layer plane, the resistance of the resistance matching layer (262, 264, 862, 864, 964) perpendicularly to the layer plane being minimal at the salient point or along the salient point,
C₁, C₂: constants independent of the distance r,
n: exponent with n>0,
m: relative weighting of the electrode resistances.

46-49. (canceled)

50. The element as claimed in claim 32, wherein the at least one resistance matching layer (262, 264, 862, 864, 964) comprises regions with differing layer thickness and/or differing layer composition and/or differing layer morphology.

51. The element as claimed in claim 32, wherein the at least one resistance matching layer (262, 264, 862, 864, 964) comprises at least one of the materials ITO, SnOₓ, InOₓ, ZnOₓ, TiOₓ, a:C—H, doped Si, PEDOT, PEDOT/PSS, PANI, anthracene, Alq₃, TDP, CuPu or NPD.

52. The element as claimed in claim 32, wherein the at least one resistance matching layer (262, 264, 862, 864, 964) is designed as a hole transport layer.

53. The element as claimed in claim 32, wherein the first (121, 221, 721) and second (122, 222, 722) electrode layers have different work functions.

54. The element as claimed in claim 32, wherein the first (121, 221, 721) and/or second (122, 222, 722) electrode layer is at least partially transparent.

55. The element as claimed in claim 32, wherein the first (121, 221, 721) and/or second (122, 222, 722) electrode layer is designed as a metal layer.

56. The element as claimed in claim 32, characterized by at least one hole injection layer and/or electron blocker layer and/or hole blocker layer and/or electron transport layer and/or hole transport layer and/or electron injection layer.

57. The element as claimed in claim 32, characterized by at least one ion transport layer and/or one ion storage layer.

58. The element as claimed in claim 32, characterized by a light absorption layer having light absorption properties varying along the layer plane.

59. The element as claimed in claim 32, characterized by an at least partially reflective layer or an at least partially reflective layer system.

60. The element as claimed in claim 32, characterized by an at least partially antireflective layer or an at least partially antireflective layer system.

61. The element as claimed in claim 32, characterized by an essentially symmetrical shape of the light exit and/or light entry surface.

62. The element as claimed in claim 32, characterized by a light exit and/or light entry surface with free, nonsymmetrical shaping.

63. The element as claimed in claim 61, characterized by a light exit and/or light entry surface which comprises at least one acutely angled region.

64. A method for producing a coated substrate in order to produce an electro-optical element, comprising the steps:
providing a substrate,
applying at least one electrode layer,
applying at least one resistance matching layer, which has an electrical resistance perpendicularly to the layer plane that varies in a horizontal direction along the layer plane, onto the substrate, wherein
at least one subsurface of the electrode layer is provided as a contact surface in order to apply and/or tap an electrical voltage and the resistance profile of the resistance matching layer depends on the surface resistance of the electrode layer and on the arrangement of the at least one contact surface.

65. The method as claimed in claim 64, wherein the application of the at least one electrode layer comprises the application of an at least partially transparent electrically conductive layer.

66. A coated substrate (802-808) for producing an electro-optical element, characterized by at least one electrode layer and a resistance matching layer (262, 264, 862, 864, 964), which has an electrical resistance perpendicularly to the layer plane that varies in a horizontal direction along the layer plane.

67. The coated substrate as claimed in claim 66, characterized in that the substrate (110, 610, 710, 810) comprises glass, a glass ceramic and/or a plastic, or a combination thereof.

68. The coated substrate as claimed in claim 66, wherein the electrode layer is at least partially transparent.

69. A method for producing an electro-optical element comprising utilizing a substrate (802-808) as claimed in claim 66.

70. A method comprising utilizing an electro-optical element as claimed claim 32
as a lighting means, or
as an illumination means, or
as a sign panel or luminescent panel or
as a variable sign plate, or
as switch or sensor illumination or
as a high- or low-resolution display, or
as a digital poster screen or advertising panel or
in lit flooring or light desks or
as a light surface for ambient illumination or
for background illumination of displays or
for special illumination,
for signaling or illumination,
as a photovoltaic element,
as an optoelectronic sensor,
as a liquid crystal element,
as an electrochromic window element, or
as an electrochromic mirror.
